(19) United States
(12) Patent Application Publication
(10) Pub. No.: US 2007/0145599 A1
(43) Pub. Date: Jun. 28, 2007

(54) Metal-insulator-metal (MIM) capacitor and methods of manufacturing the same

(75) Inventor: Yung Pil Kim, Seoul (KR)

Correspondence Address: MAYER, BROWN, ROWE & MAW LLP, 1909 K STREET, N.W., WASHINGTON, DC, 20006, US

(73) Assignee: Dongbu Electronics Co., Ltd.

(21) Appl. No.: 11/643,911

(22) Filed: Dec. 22, 2006

(30) Foreign Application Priority Data
Dec. 28, 2005 (KR) 10-2005-0131396

(51) Int. Cl. H01L 23/48

(52) U.S. Cl. 257/774

(57) ABSTRACT

A method of manufacturing a Metal-Insulator-Metal (MIM) capacitor and an MIM capacitor formed by the method are described. The method comprises sequentially forming a dielectric film and an interlayer insulating film on a silicon substrate on which lower copper wiring is formed, forming via holes by selectively etching the interlayer insulating film, and defining a region for the formation of an upper electrode of the capacitor, forming trenches by selectively etching the interlayer insulating film, and forming a capacitor having a lower copper wiring/dielectric film/upper electrode structure by filling the formed trenches with copper and filling the defined region for the formation of the upper electrode with copper.

### CROSS-REFERENCE TO RELATED APPLICATIONS

The present application claims priority of Korean patent application number 10-2005-0131396, filed on Dec. 28, 2005, which is incorporated herein by reference in its entirety.

### FIELD OF THE INVENTION

The present invention relates to semiconductor technology and, in particular, to a metal-insulator-metal (MIM) capacitor, and to a method of manufacturing semiconductor devices including a (“MIM”) capacitor.

### BACKGROUND

Recently, copper wiring has been used in a process of manufacturing semiconductor devices to reduce resistor capacitor (RC) delay. A damascene method, i.e., selectively etching an insulating film and filling the etched insulating film with copper, is used to form the copper wiring in the semiconductor device.

Meanwhile, capacitors are commonly used semiconductor elements, and a Metal-Insulator-Metal (MIM) capacitor is widely used.

A process of forming an MIM capacitor through a process of forming copper wiring using a dual damascene method is described with reference to FIGS. 1A to 1E below.

First, as shown in FIG. 1A, a silicon nitride film 6 and an interlayer insulating film 8 are formed on a silicon substrate 2 in which lower copper wiring 4 is formed.

Thereafter, as shown in FIG. 1B, a via hole 11 and trenches 13 are formed through a photolithography process and an etching process.

The via hole 11 and the trenches 13 formed as described above are filled with copper through an electroplating process, and upper copper wiring 14 is formed through a planarization process as shown in FIG. 1C. Part of the upper copper wiring 14 functions as an electrode for forming the MIM capacitor in the following process.

Referring to FIG. 1D, in order to form the MIM capacitor using the part of the upper copper wiring 14 as an electrode, an insulating film 10 and an upper electrode film 12 are formed on the interlayer insulating film 8. Thereafter, a mask 15 for forming an upper electrode is aligned on the upper electrode film 12.

Thereafter, as shown in FIGS. 1D and 1E, an upper electrode 12a is formed through a photolithography process and an etching process. Accordingly, the part of the upper copper wiring 14 functions as a lower electrode 14a. An MIM capacitor A, including the sequential formation of the insulating film 10 and the upper electrode 12a on the lower electrode 14a, is formed.

Referring to FIGS. 1E and 1F, a second interlayer insulating film 18 is further formed on the insulating film 10, and then a damascene process is performed again. Therefore, an electrode terminal 16a for electrical connection with the lower electrode 14a of the MIM capacitor A is connected with the lower electrode 14a through a via hole 17a. Likewise, an electrode terminal 16b for electrical connection with the upper electrode 12a is connected with the upper electrode 12a through another via hole 17b.

As described above, in the conventional process of forming an MIM capacitor in a semiconductor device, additional insulating film and upper electrode film 12 (see FIG. 1D) must be separately formed on the copper wiring formed using a damascene method. Furthermore, an exposing process and a photolithography process are additionally required to pattern the insulating film and the upper electrode film 12, thus increasing the manufacturing cost and time. Moreover, as manufacturing processes become complicated, the yield is often reduced because defects may occur in each process.

### SUMMARY

Therefore there is a need to provide a method of manufacturing an MIM capacitor that simplifies the process, thus being capable of reducing the manufacturing cost and time.

In accordance with some embodiments of the present invention, there is provided a method of manufacturing an MIM capacitor, the method comprising sequentially forming a dielectric film and an interlayer insulating film on a silicon substrate on which lower copper wiring is formed; forming via holes by selectively etching the interlayer insulating film, and defining a region for the formation of an upper electrode of the capacitor; forming trenches by selectively etching the interlayer insulating film; and forming a capacitor having a lower copper wiring/dielectric film/upper electrode structure by filling the formed trenches with copper and filling the defined region for the formation of the upper electrode with copper.

In some embodiments, the dielectric film may be formed using any of a silicon oxide film and a silicon nitride film.

In accordance with other embodiments of the present invention, there is provided an MIM capacitor, which comprises: lower copper wiring, wherein part of the lower copper wiring is used as a lower electrode of the capacitor; a dielectric film formed over the lower copper wiring; a lower electrode terminal, formed through the dielectric film, for electrically connecting the lower electrode to outside of the capacitor; a via hole, formed through the dielectric film under the lower electrode terminal, for electrically connecting the lower electrode terminal to the lower electrode; and an upper copper electrode formed over the dielectric film, and surrounded by an interlayer insulating film.

In some embodiments, the upper copper electrode has the same height as that of the interlayer insulating film.

In some embodiments, the upper copper electrode has the same height as that of the lower electrode terminal.

In some embodiments, the lower electrode terminal and the via hole comprise copper.

### BRIEF DESCRIPTION OF THE DRAWINGS

The above and other objects and features of the present invention will become apparent from the following description of some embodiments given in conjunction with the accompanying drawings, in which:

FIGS. 1A to 1F are sectional views illustrating a conventional method of manufacturing a semiconductor device including an MIM capacitor; and

FIGS. 2A to 2E are sectional views illustrating a method of manufacturing a semiconductor device including an MIM capacitor according to the present invention.

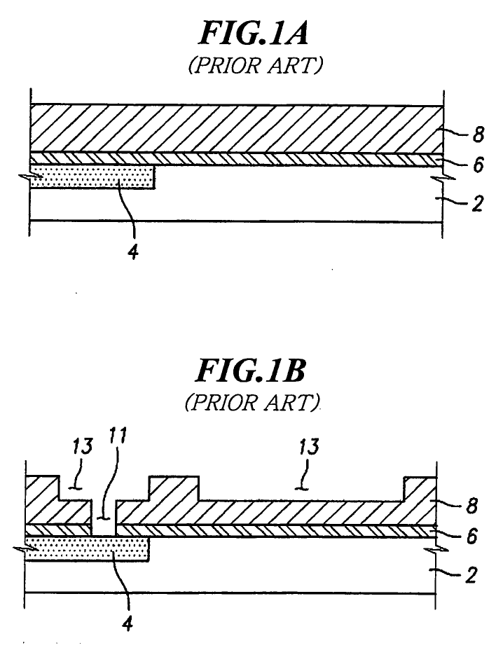

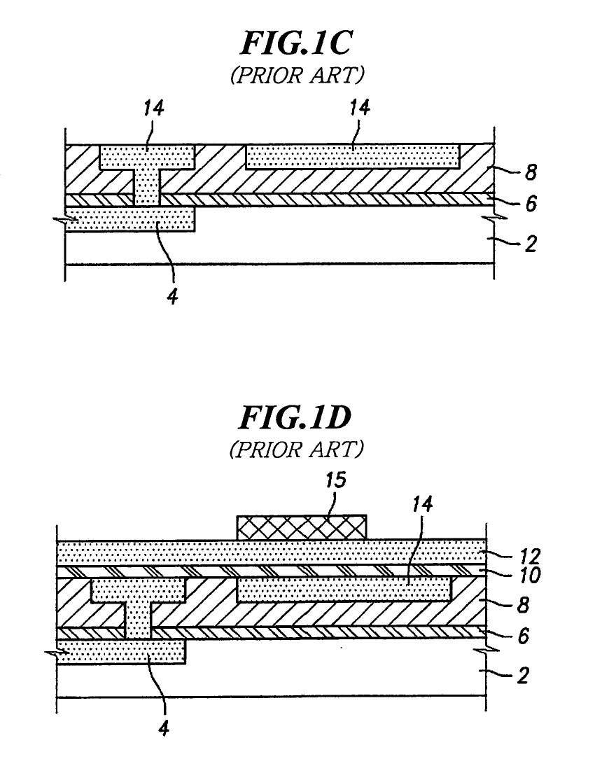

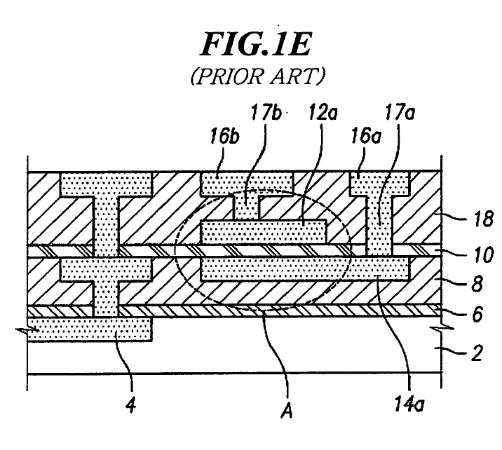

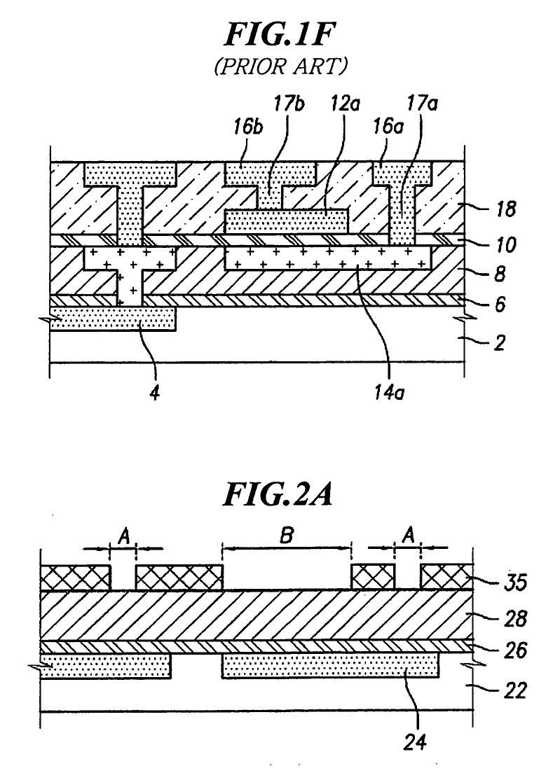

### DETAILED DESCRIPTION

Hereinafter, some embodiments of the present invention will be described with reference to the accompanying drawings.

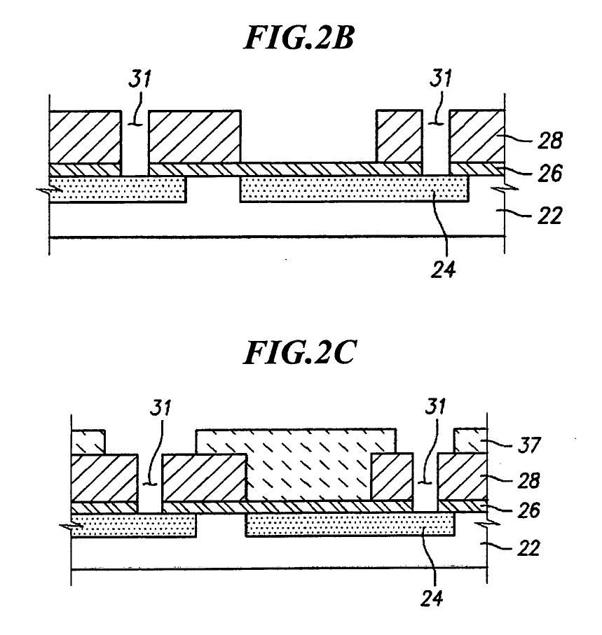

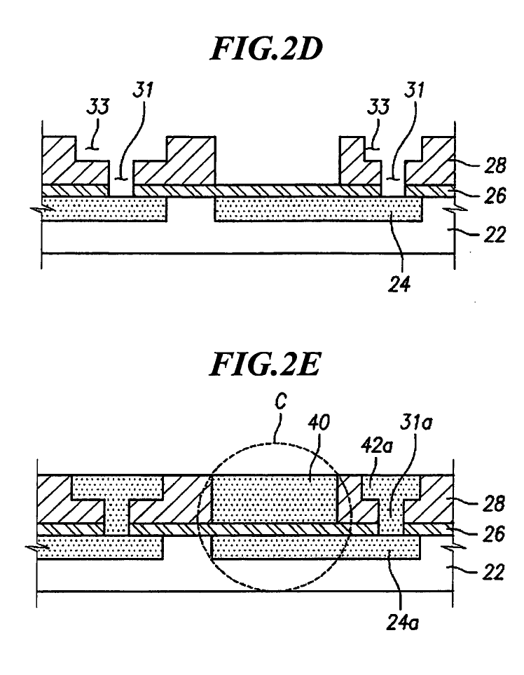

FIGS. 2A to 2E are sectional views illustrating a method of manufacturing a semiconductor device including an MIM capacitor according to the present invention.

In the method of manufacturing a semiconductor device including an MIM capacitor, a dielectric film 26 and an interlayer insulating film 28, as shown in FIG. 2A, are sequentially formed on a silicon substrate 22 in which lower copper wiring 24 is formed. The dielectric film 26 may be formed using a silicon oxide (SiO₂) film or a silicon nitride (Si₃N₄) film. Furthermore, in some embodiments the dielectric film 26 is formed to have a thickness ranging from 500 Å to 1000 Å.

Thereafter, a first photoresist pattern 35 is formed on the resultant product to define regions in which via holes and the MIM capacitor will be formed. That is, the first photoresist pattern 35 is aligned so as to define regions A, in which the via holes will be formed, and region B, in which the MIM capacitor will be formed.

The dielectric film 26 and the interlayer insulating film 28 are selectively etched using the first photoresist pattern 35 as a mask, so that via holes 31 are formed, and the interlayer insulating film 28 corresponding to region B, in which a portion of the MIM capacitor will be formed, is removed, as shown in FIG. 2B.

Thereafter, a second photoresist pattern 37 for forming trenches is formed on the interlayer insulating film 28, as shown in FIG. 2C. In this case, the second photoresist pattern 37 is also formed in the region, in which the MIM capacitor will be formed, to prevent the dielectric film 26, which functions as the dielectric of the capacitor, from being etched.

Thereafter, the interlayer insulating film. 28 is selectively etched using the second photoresist pattern 37 as a mask, and thus trenches 33 are formed, as shown in FIG. 2D.

Thereafter, the via holes 31, the trenches 33, and the region in which the upper electrode 40 of the MIM capacitor will be formed are filled with copper. Accordingly, part of the lower copper wiring 24 is used as a lower electrode 24a, and the MIM capacitor C, including the dielectric film 26 and the upper electrode 40 that are formed on the lower electrode 24a, is formed.

On one side of the lower electrode 24a, a lower electrode terminal 42a for electrically connecting the lower electrode 24a to the outside is connected to the lower electrode 24a through a via hole 31a. Meanwhile, the upper electrode 40 is formed to have the same height as that of the interlayer insulating film 28 and is connected to external wiring. Also, the upper electrode 40 is formed to have the same height as that of the lower electrode terminal 42a which has been formed to pass through the interlayer insulating layer 28.

As described above with reference to some embodiments, the method of forming a capacitor can simplify the process of manufacturing a semiconductor device by eliminating the conventional process of separately forming the upper electrode film and etching it. Accordingly, the defects that may occur as processes become complicated can be reduced and, at the same time, the manufacturing cost and time can be reduced.

In the present specification and drawings, some embodiments of the present invention are disclosed, and specific terms are used for this purpose. These terms are used to easily describe the technical details of the present invention and promote understanding of the invention, but are not used to limit the scope of the present invention. It will be apparent to those having ordinary skill in the art of the present invention that other modifications based on the technical spirit of the present invention, other than the embodiment disclosed herein, may be implemented.

What is claimed is:

1. A method of manufacturing a Metal-Insulator-Metal (MIM) capacitor, comprising:
sequentially forming a dielectric film and an interlayer insulating film on a silicon substrate on which lower copper wiring is formed;
forming via holes by selectively etching the interlayer insulating film;
defining a region for the formation of an upper electrode of the capacitor;
forming trenches by selectively etching the interlayer insulating film; and
forming a capacitor having a lower copper wiring/dielectric film/upper electrode structure by filling the formed trenches with copper and filling the defined region for the formation of the upper electrode with copper.

2. The method of claim 1, further comprising planarizing the copper wiring and the upper electrode formed by the forming a capacitor.

3. The method of claim 1, wherein the forming a dielectric film comprises using at least one of a silicon oxide film and a silicon nitride film.

4. The method of claim 3, wherein the forming a dielectric film comprises forming the dielectric film to a thickness ranging from approximately 500 Å to approximately 1000 Å.

5. A Metal-Insulator-Metal (MIM) capacitor, comprising:
lower copper wiring, wherein part of the lower copper wiring is used as a lower electrode of the capacitor;
a dielectric film formed over the lower copper wiring;
a lower electrode terminal, formed through the dielectric film, for electrically connecting the lower electrode to outside of the capacitor;
a via hole, formed through the dielectric film under the lower electrode terminal, for electrically connecting the lower electrode terminal to the lower electrode; and
an upper copper electrode formed over the dielectric film, and surrounded by an interlayer insulating film;
wherein the upper copper electrode has the same height as that of the interlayer insulating film.

6. The capacitor of claim 5, wherein the upper copper electrode has the same height as that of the lower electrode terminal.

7. The capacitor of claim 5, wherein the lower electrode terminal and the via hole comprise copper.
